(19) United States
(12) Patent Application Publication
(10) Pub. No.: US 2006/0029732 A1
(43) Pub. Date: Feb. 9, 2006

(54) Vapor deposited functional organic coatings

(76) Inventors: Boris Kobrin, Walnut Creek, CA (US); William R. Ashurst, Auburn, AL (US); Jeffrey D. Chinn, Foster City, CA (US); Romuald Nowak, Cupertino, CA (US)

Correspondence Address: Shirley L. Church, Esq., P.O. Box 61929, Sunnyvale, CA, 94088, US

(21) Appl. No.: 10/912,656

(22) Filed: Aug. 4, 2004

(51) Int. Cl. C23C 16/00

(52) U.S. Cl. 427/248.1; 427/255.6

(57) ABSTRACT

We have developed an improved vapor-phase deposition method and apparatus for the application of organic films/coatings containing a variety of functional groups on substrates. Most substrates can be coated using the method of the invention. The substrate surface is halogenated using a vaporous halogen-containing compound, followed by a reaction with at least one organic molecule containing at least one nucleophilic functional group capable of reacting with a halogenated substrate surface. The halogenation of the substrate surface and the subsequent reaction with the organic molecule nucleophilic functional group are carried out in the same process chamber in a manner such that the halogenated substrate surface does not lose its functionality prior to reaction with the nucleophilic functional group(s) on the organic molecule. Typically the process chamber is operated under a pressure ranging from about 1 mTorr to about 10 Torr.

This application is related to U.S. application Ser. No. 10/759,857, filed Jan. 16, 2004 and entitled “Apparatus And Method For Controlled Application Of Reactive Vapors To Produce Thin Films And Coatings” and to U.S. application Ser. No. 10/862,047, filed Jun. 4, 2004 and entitled “Controlled Deposition Of Silicon-Containing Coatings Adhered By An Oxide Layer”, each of which is hereby incorporated by reference it its entirety.

### BACKGROUND OF THE INVENTION

1. Field of the Invention

The present invention pertains to a method, and to the resulting structure which is created by the method, of depositing a coating from vaporous precursors in a manner such that the surface of the deposited coating is functionally designed on a nanometer scale. The method is described with reference to deposition of an organic coating where the precursor used to form the coating contains a nucleophilic functional group capable of reacting with a specially prepared substrate surface.

2. Brief Description of the Background Art

Integrated circuit (IC) device fabrication, micro-electromechanical systems (MEMS) fabrication, microfluidics, bioactive structures, biochips, and microstructure fabrication in general make use of layers or coatings of materials which are deposited on a substrate for various purposes. In some instances, the layers are deposited on a substrate and then are subsequently removed, such as when the layer is used as a patterned masking material and then is subsequently removed after the pattern is transferred to an underlying layer. In other instances, the layers are deposited to perform a function in a device or system and remain as part of the fabricated device.

There are numerous methods for depositing a thin film or a coating, such as, for example: Sputter deposition, where an ion plasma is used to sputter atoms from a target material (commonly a metal), and the sputtered atoms deposit on the substrate; chemical vapor deposition, where activated (e.g. by means of plasma, radiation, or temperature, or a combination thereof) species react either in a vapor phase (with subsequent deposition of the reacted product on the substrate) or react on the substrate surface to produce a reacted product on the substrate; evaporative deposition, where evaporated material condenses on a substrate to form a layer; and, spin-on, spray-on, wiped, or dipped-on deposition, typically from a solvent solution of the coating material, where the solvent is subsequently rinsed or evaporated off to leave the coating material on the substrate.

In many applications where the wear on the coating is likely to occur due to mechanical contact or where fluid flow is to occur over the substrate surface on which the layer of coating is present, it is helpful to have the coating chemically bonded directly to the substrate surface via chemical reaction of active species which are present in the coating reactants/materials with active species on the substrate surface. In addition, particular precursor materials may be selected which are known to provide particular functional moieties.

With respect to layers and coatings which are chemically bonded to the substrate surface, there are a number of areas of particular current interest. By way of example, and not by way of limitation, such coatings may be used for biotechnology applications, where the surface wetting properties and chemical functionality of the coating are useful for analytical purposes, for selectively attaching molecules to the surface, for controlling fluid flow and sorting of fluid components, and for altering the composition of components which come into contact with the surface, for example. Such coatings may also be used in the field of integrated circuitry, or when there is a combination of integrated circuitry with mechanical systems, which are referred to as micro-electromechanical systems, or MEMS. Due to the nanometer size scale of some of applications for coatings exhibiting specialized functionality, a need has grown for improved methods of controlling the formation of the coating, including the formation of individual layers within a multi-layered coating. Historically, these types of coatings were deposited by contacting a substrate surface with a liquid phase. While this technique enables efficient coating deposition, it frequently results in limited film property control and requires expensive liquid chemical handling. In the case of coating a surface of a nanometer scale device, use of liquid phase processing limits device yield due to contamination and capillary forces. More recently, deposition of coatings from a vapor-phase has been used in an attempt to improve coating properties. However, the common vapor-phase deposition methods may not permit sufficient control of the molecular level reactions taking place during the deposition of surface bonding layers or during the deposition of functional coatings, when the deposited coating needs to function on a nanometer (nm) scale.

Organic layers are actively used in biomedical research, where microfluidic or microarray chips are fabricated for screening of chemical and biological materials, toxicology, gene expression analysis, etc. These applications require a high level of flexibility in deposition of a variety of organic molecules with different functionalities on a micro device. Although silicon has been used as a substrate for such applications, other materials have been used such as glass (typically soda lime glass), metals (stainless steel and copper alloys, by way of example and not limitation), and plastics (PDMS, PMMA, Polycarbonate, and Acrylic, by way of example and not by way of limitation).

Methods have been developed for depositing silane-terminated organic molecules on silicon and thiols on gold. Although these techniques are widely used, they do not provide the required level of functional flexibility due to the limited availability of synthesized silane-based and thiol-based precursors with desired functionality.

For purposes of illustrating methods of coating formation where vaporous and liquid precursors are used to deposit a coating on a substrate, applicants would like to mention the following publications and patents which relate to methods of coating formation, for purposes of illustration. Applicants would like to make it clear that some of this Background Art is not prior art to the present invention. It is mentioned here because it is of interest to the general subject matter.

In an article by Barry Arkles entitled “Tailoring surfaces with silanes”, published in CHEMTECH, in December of 1977, pages 766-777, the author describes the use of organo silanes to form coatings which impart desired functional characteristics to an underlying oxide-containing surface. In particular, the organo silane is represented as RₙSiX₍₄₋ₙ₎ where X is a hydrolyzable group, typically halogen, alkoxy, acyloxy, or amine. Following hydrolysis, a reactive silanol group is said to be formed which can condense with other silanol groups, for example, those on the surface of siliceous fillers, to form siloxane linkages. Stable condensation products are said to be formed with other oxides in addition to silicon oxide, such as oxides of aluminum, zirconium, tin, titanium, and nickel. The R group is said to be a nonhydrolyzable organic radical that may possess functionality that imparts desired characteristics. The article also discusses reactive tetra-substituted silanes which can be fully substituted by hydrolyzable groups and how the silicic acid which is formed from such substituted silanes readily forms polymers such as silica gel, quartz, or silicates by condensation of the silanol groups or reaction of silicate ions. Tetrachlorosilane is mentioned as being of commercial importance since it can be hydrolyzed in the vapor phase to form amorphous fumed silica.

The article by Dr. Arkles shows how a substrate with hydroxyl groups on its surface can be reacted with a condensation product of an organosilane to provide chemical bonding to the substrate surface. The reactions are generally discussed and, with the exception of the formation of amorphous fumed silica, the reactions are between a liquid precursor and a substrate having hydroxyl groups on its surface. A number of different applications and potential applications are discussed.

In an article entitled “Organized Monolayers by Adsorption. 1. Formation and Structure of Oleophobic Mixed Monolayers on Solid Surfaces”, published in the Journal of the American Chemical Society, Jan. 2, 1980, pp. 92-98, Jacob Sagiv discussed the possibility of producing oleophobic monolayers containing more than one component (mixed monolayers). The article is said to show that homogeneous mixed monolayers containing components which are very different in their properties and molecular shape may be easily formed on various solid polar substrates by adsorption from organic solutions. Irreversible adsorption is said to be achieved through covalent bonding of active silane molecules to the surface of the substrate.

In June of 1991, D. J. Ehrlich and J. Melngailis published an article entitled “Fast room-temperature growth of SiO₂ films by molecular-layer dosing” in Applied Physics Letters 58 (23), pp. 2675-2677. The authors describe a molecular-layer dosing technique for room-temperature growth of α—SiO₂ thin films, which growth is based on the reaction of H₂O and SiCl₄ adsorbates. The reaction is catalyzed by the hydrated SiO₂ growth surface, and requires a specific surface phase of hydrogen-bonded water. Potential applications such as trench filling for integrated circuits and hermetic ultrathin layers for multilayer photoresists are mentioned. Excimer-laser-induced surface modification is said to permit projection-patterned selective-area growth on silicon.

An article entitled “Atomic Layer Growth of SiO₂ on Si(100) Using The Sequential Deposition of SiCl₄ and H₂O” by Sneh et al. in Mat. Res. Soc. Symp. Proc. Vol 334, 1994, pp. 25-30, describes a study in which SiO₂ thin films were said to be deposited on Si(100) with atomic layer control at 600° K (≅327° C.) and at pressures in the range of 1 to 50 Torr using chemical vapor deposition (CVD).

In U.S. Pat. No. 5,372,851, issued to Ogawa et al. on Dec. 13, 1995, a method of manufacturing a chemically adsorbed film is described. In particular a chemically adsorbed film is said to be formed on any type of substrate in a short time by chemically adsorbing a chlorosilane based surface active-agent in a gas phase on the surface of a substrate having active hydrogen groups. The basic reaction by which a chlorosilane is attached to a surface with hydroxyl groups present on the surface is basically the same as described in other articles discussed above.

Ashish Bansal et al., in an article entitled “Alkylation of Silicon Surfaces Using a Two-Step Halogenation/Grignard Route”, J. Am. Chem. Soc. 1996, 118, 7225-7226, describe a strategy to functionalize HF-etched Si surfaces which involves halogenation and subsequent reaction with alkyl Grignard or alkyl lithium reagents. They report vibrational spectroscopic and temperature programmed desorption data which is said to confirm that the alkyl groups are bonded covalently to the Si surface. They claim to have demonstrated that undesirable oxidation of Si can be impeded using their method in a variety of environments while providing surfaces of high electrical quality.

In an article by X. -Y. Zhu et al, entitled “Chemical Vapor Deposition of Organic Monolayers on Si(100) via Si—N linkages, Langmuir 1999, 15, 8147-8154, the authors describe soft thin films, i.e., organic monolayers, which are assembled on Si(100) from chemical vapor deposition (CVD) of amine molecules (R—NH₂) on a monochloride-covered surface. The N anchor is said to be bridged between two surface Si atoms while the hydrocarbon group remains intact. This same subject matter is discussed in U.S. Pat. No. 6,403,382, issued Jun. 11, 2002 to Zhu et al., which describes an approach for the covalent assembly of organic molecules on silicon surfaces. This is achieved by the reaction between a nucleophilic functional group and a halogenated silicon surface. The nucleophilic functional group is said to provide an anchor which bridges between two surface silicon atoms. This is illustrated in FIG. 1, when an organic amine is used as the nucleophilic functional group. The resulting organic layer is said to be thermally stable. The method is said to be generally applicable for the assembly of functional organic molecules under a vacuum environment or in liquid solution. The method is said to contemplate silicon substrates in which silicon is available for reaction with halogen and organic nucleophilic compounds. In a preferred embodiment example, the surface of a silicon substrate is cleaned by heating a native oxide covered surface in a vacuum environment to above 1250° K (977° C.). The resulting surface was exposed to a saturation dose of Cl₂ gas in vacuum at 300° K (27° C.) to form the monochloride Si(100)-(2×1)Cl surface, which was subsequently transferred to a high vacuum reactor where amine-containing molecules were attached at a gas pressure of 1×10⁻² Torr at a surface temperature of450° K (177° C.) for a time period of about 2 hours. Alternatively, Cl₂ gas is applied to a clean silicon substrate at 0.2 Torr while the substrate is illuminated by a 300 W tungsten lamp for 2 minutes.

U.S. Patent Publication No. US 2002/0065663 A1, published on May 30, 2002, and titled “Highly Durable Hydrophobic Coatings And Methods”, describes substrates which have a hydrophobic surface coating comprised of the reaction products of a chlorosilyl group containing compound and an alkylsilane. The substrate over which the coating is applied is preferably glass. In one embodiment, a silicon oxide anchor layer or hybrid organo-silicon oxide anchor layer is formed from a humidified reaction product of silicon tetrachloride or trichloromethylsilane vapors at atmospheric pressure. Application of the oxide anchor layer is, followed by the vapor-deposition of a chloroalkylsilane.

Simultaneous vapor deposition of silicon tetrachloride and dimethyldichlorosilane onto a glass substrate is said to result in a hydrophobic coating comprised of cross-linked polydimethylsiloxane which may then be capped with a fluoroalkylsilane (to provide hydrophobicity). The substrate is said to be glass or a silicon oxide anchor layer deposited on a surface prior to deposition of the cross-linked polydimethylsiloxane. The substrates are cleaned thoroughly and rinsed prior to being placed in the reaction chamber.

Other known related references pertaining to coatings deposited on a substrate surface from a vapor include the following, as examples and not by way of limitation. U.S. Pat. No. 5,576,247 to Yano et al., issued Nov. 19, 1996, entitled: “Thin layer forming method where hydrophobic molecular layers preventing a BPSG layer from absorbing moisture”. U.S. Pat. No. 5,602,671 of Hornbeck, issued Feb. 11, 1997, which describes low surface energy passivation layers for use in micromechanical devices. An article entitled “Vapor phase deposition of uniform and ultrathin silanes”, by Yuchun Wang et al., SPIE Vol. 3258-0277-786X(98) 20-28, in which the authors describe uniform, conformal, and ultrathin coatings needed on the surface of biomedical microdevices such as microfabricated silicon filters, in order to regulate hydrophilicity and to minimize unspecific protein adsorption. Jian Wang et al., in an article published in Thin Solid Films 327-329 (1998) 591-594, entitled: “Gold nanoparticulate film bound to silicon surface with self-assembled monolayers”, discuss a method for attaching gold nanoparticles to silicon surfaces with a self aligned monolayer (SAM) used for surface preparation”.

T. M. Mayer et al. describe a “Chemical vapor deposition of fluoroalkylsilane monolayer films for adhesion control in microelectromechanical systems” in J. Vac. Sci. Technol. B 18(5), September/October 2000. This article mentions the use of a remotely generated microwave plasma for cleaning a silicon substrate surface prior to film deposition, where the plasma source gas is either water vapor or oxygen.

Various methods useful in applying layers and coatings to a substrate have been described above, and there is not sufficient space available here to discuss even a minor portion of the numerous patents and publications which relate to the deposition of functional coatings on substrates. However, upon reading these informative descriptions, it becomes readily apparent that control of coating deposition on a molecular level is not addressed in detail in most instances. When this is discussed, the process is typically described in generalized terms like those mentioned directly above, which terms are not enabling to one skilled in the art, but merely suggest experimentation. To provide a monolayer or a few layers of a functional coating on a substrate surface which is functional or exhibits features on a nanometer scale, it is necessary to tailor the coating by controlling its deposition precisely. Without precise control of the deposition process, the coating may lack uniform surface coverage, leaving portions of the substrate exposed. Or, the coating may differ in structural composition and homogenity across the surface of the substrate. Any one of these non-uniformities may result in functional discontinuities and defects on the coated substrate surface which are unacceptable for the intended application of the coated substrate.

U.S. patent application Ser. No. 10/759,857 of the present applicants describes processing apparatus which can provide specifically controlled, accurate delivery of precise quantities of reactants to the process chamber, as a means of improving control over a coating deposition process. The subject matter of the '857 application has been incorporated by reference in its entirety into the present application. The focus of the present application is related to a method of attaching functional organic coatings to a variety of substrates, where the method requires the delivery of accurate quantities of reactive materials, and provides a uniform, functional coating on a nanometer scale. The coating exhibits sufficient uniformity of thickness, chemical composition and structural composition over the substrate surface that such nanometer scale functionality is achieved.

Despite all of the interest in the attachment of functional groups to silicon or silicon oxide, there remains a need in the bio IC and MEMS fabrication industries for a straight forward method of attaching functional groups to a substrate surface ( not only to silicon or silicon oxide, but also to a variety of other materials) in a controlled manner which permits tailoring of a substrate surface to have a particular structure which provides specific functional properties.

### SUMMARY OF THE INVENTION

We have developed an improved vapor-phase deposition method and apparatus for the application of organic molecules having a variety of functional groups as films (coatings) on a variety of different substrate materials. The substrate surface is halogenated using a specialized technique which is dependent on the substrate. The precursors for the organic molecules contain at least one nucleophilic functional group capable of reacting with a halogenated substrate surface. The halogenation of the substrate surface and the subsequent reaction with the organic molecule nucleophilic functional group are carried out in the same process chamber in a manner such that the halogenated substrate surface does not lose its functionality prior to reaction with the nucleophilic functional group(s) on the organic molecule. Typically the process chamber is operated under a pressure ranging from about 10 mTorr to about 10 Torr. It would be possible to operate at a lower pressure (this is more expensive because of the kind of vacuum pump required), but a lower pressure is not required for most applications.

The substrate surface preparation frequently includes the use of a plasma or ozone treatment. Preferably, the plasma is a remotely-generated plasma. One preferred plasma is generated from an oxygen-containing plasma source gas. This substrate surface preparation removes any organic contamination from the substrate surface, and in some instances activates the surface for reaction. Depending on the substrate, the substrate surface preparation may not be required if the substrate surface is very clean and the substrate is treated to apply an adhesion promoting layer.

Application of an adhesion promoting layer is optional with respect to some substrates, for example those which have an oxide layer on their surface. For other substrates, such as most plastics, application of an adhesion promoting layer may be necessary. Application of an adhesion promoting layer is generally carried out by reacting the substrate surface with halogen-containing gaseous compound, which is typically used in combination with water vapor, in a low pressure (pressure ranging from about 5 Torr to about 50 Torr environment. However, at pressures above about 10 Torr reactive materials are typically in excess of the amount needed to provide the adhesion promoting layer, and reactive materials are wasted. Examples of such halogen-containing compounds include SiCl₄, Si₂OCl₆, SnCl₂, PCl₅, and SOCl₂, not by way of limitation.

Relative vapor pressure ratios of the halogen-containing gaseous compound to the water vapor in the process chamber range from about 1:4 to about 1:10, depending on which halogen-containing compound is used. The relative vapor pressures are set so that not all of the water present in the process chamber will be consumed in the reaction. Typically the reaction temperature ranges from about 25° C. to about 60° C., and the reaction time period ranges from about 3 minutes to about 15 minutes. The process in which SiCl₄ is the halogen-containing compound creates a thin layer of silicon oxide on top of a wide variety of substrates, where the hydroxylated silicon oxide provides a dense —OH terminated surface for subsequent modification to the halogen-terminated surface of the present invention.

The halogenation of the substrate surface, with and/or without an adhesion oxide layer, is typically carried out by first pumping down the process chamber in which the substrate is present to a pressure of about 15 mTorr or less, at a temperature ranging from about 25° C. to about 50° C. for a time period sufficient to reduce the residual vapor pressure of water present in the chamber. Halogenation of the hydroxylated substrate surface is done by exposing the surface to a halogen-containing compound which is capable of reacting with the —OH active sites on the substrate surface. Examples of preferred halogen-containing compounds include compounds represented as RₙSiX₍₄₋ₙ₎ where X is a hydrolyzable group, typically halogen, alkoxy, acyloxy, or amine, and Rₙ represents an organic moiety. Chlorosilanes and chlorosiloxanes such as SiCl₄ or Si₂OCl₆ work particularly well. This process builds a layer of halogenated molecules on an oxide surface which was originally present or which was produced by an adhesion layer deposition. An additional pump down of the chamber, followed by exposure of the surface to additional halogen-containing compound may be used to scavenge all residual water in the process chamber and to ensure that complete halogenation of the substrate surface is achieved.

Halogenated layers comprised of —SiCl₃ or ═SiCl₂ groups, created in the manner described above, have performed well in the method of the invention. The halogenation process typically is carried out at a process chamber pressure ranging from about 1 Torr to about 5 Torr and at a temperature ranging from about 25° C. to about 100° C., where the reaction time ranges from about 1 minute to about 10 minutes. When SiCl₄ is used as the precursor for formation of the halogenated layer on the substrate surface, for example, the pressure in the process chamber is in the range of about 1 Torr to about 4 Torr and the reaction is carried out for a time period of about 3 to 5 minutes, and then the process chamber is pumped down and the application of SiCl₄ is repeated, typically at least one additional time.

The organic layer deposition over the halogenated substrate surface is accomplished by exposing the halogenated surface to an organic molecule containing at least one nucleophilic functional group, where the organic molecule is in a vaporous state. The reaction between the halogenated surface and the organic molecule is carried out in a low pressure environment, where the pressure typically ranges from about 0.1 Torr to about 10 Torr. For example, when the organic molecule is hexanediol, the pressure in the process chamber is typically in the range of about 0.1 Torr to about 1 Torr, and more typically in the range of about 0.1 Torr to about 0.3 Torr. The reaction is typically carried out at a temperature ranging from about 25° C. to about 100° C., and more typically ranging from about 50° C. to about 60° C., for a time period ranging from about 10 minutes to about 30 minutes. Often the time period is in the range of about 15 minutes. In some instances, depending on the nucleophilic organic molecule and other process variable conditions, the process chamber may be pumped down, additional nucleophilic functional organic molecule reagent added, and the reaction process may be repeated at least once. Typically the cycle in which the process chamber is pumped down and the nucleophilic organic reagent is charged is carried out in the range of 2 to 5 times, with a 4 cycle process providing excellent results.

The coating formation method typically, but not necessarily, employs a batch-like addition and mixing of all of the reactants to be consumed in a given process step, whether that step is one in a series of steps or is the sole step in a coating formation process. In some instances, the coating formation process may include a number of individual steps such as the formation of an oxide on a substrate surface, hydrolization of the oxide surface, conversion of the hydrolyzed oxide surface to a halogen-containing surface, and reaction of the halogen-containing surface with a nucleophilic functional organic molecule, where repetitive reactive processes may be carried out in any individual step.

The apparatus used to carry out the method provides for the addition of a precise amount of each of the reactants to be consumed in a single reaction step of the coating formation process. The apparatus may provide for precise addition of quantities of different combinations of reactants during each individual step when there are a series of different individual steps in the coating formation process.

In addition to the control over the amount of reactants added to the process chamber, the present invention requires precise control over the cleanliness of the substrate, the order of reactant(s) introduction, the total pressure (which is typically less than atmospheric pressure) in the process chamber, the partial vapor pressure of each vaporous component present in the process chamber, the temperature of the substrate and chamber walls. The control over this combination of variables determines the deposition rate and properties of the deposited layers. By varying these process parameters, we control the amount of the reactants available, the density of reaction sites, and the film growth rate, which is the result of the balance of the competitive adsorption and desorption processes on the substrate surface, as well as any gas phase reactions.

The coating deposition process is carried out in a vacuum chamber where the total pressure is lower than atmospheric pressure and the partial pressure of each vaporous component making up the reactive mixture is specifically controlled so that formation and attachment of molecules on a substrate surface are well controlled processes that can take place in a predictable and reproducible manner. As previously mentioned, the surface concentration and location of reactive species are controlled using total pressure in the processing chamber, the kind and number of vaporous components present in the process chamber, the partial pressure of each vaporous component in the chamber, temperature of the substrate, temperature of the process chamber walls, and the amount of time that a given set of conditions is maintained.

In some instances, where it is desired to have a particularly uniform growth of the composition across the coating surface, or a variable composition across the thickness of a multi-layered coating, more than one batch of reactants may be charged to the process chamber during formation of the coating.

The coatings formed by the method of the invention are sufficiently controlled that the surface roughness of the coating in terms of RMS is less than about 10 nm, and is typically in the range of about 0.1 nm to 5 nm.

In instances where it is desired to create multilayered coatings, it is advisable to use oxygen plasma treatment to regenerate and to hydroxylize an oxide surface on the substrate, which oxide surface can serve as the substrate for formation of a new halogenated surface which is subsequently reacted with a nucleophilic functional organic molecule. This oxygen plasma treatment activates dangling bonds on the substrate surface, which dangling bonds can be reacted by exposure to a controlled partial pressure of water vapor to create an increased concentration of OH reactive sites on the substrate surface. The coating deposition process may then be repeated, increasing the coating thickness.

A computer driven process control system may be used to provide for a series of additions of reactants to the process chamber in which the layer or coating is being formed. This process control system typically also controls other process variables, such as, (for example and not by way of limitation), total process chamber pressure (typically less than atmospheric pressure), substrate temperature, temperature of process chamber walls, temperature of the vapor delivery manifolds, processing time for given process steps, and other process parameters if needed

### BRIEF DESCRIPTION OF THE DRAWINGS

FIG. 1 shows a cross-sectional schematic of one embodiment of the kind of an apparatus which can be used to carry out a vapor deposition of a coating in accordance with the method of the present invention.

FIG. 2A-1 shows a reaction schematic where a starting substrate structure 200A, which has no hydroxyl groups present on the substrate surface, is reacted with vaporous silicon tetrachloride 208 and water vapor 206, to produce a silicon oxide layer 210 with newly formed —OH moieties 214 on the surface and within the generally silicon oxide structure 210 of reacted structure 220A. If the amount of water vapor is deficient, some silicon-chlorine bonds may also be present within the oxide structure.

FIG. 2A-2 shows a reaction schematic for an alternative starting substrate structure 200B, where there are hydroxyl groups 204 initially present on the substrate surface. After a reaction of vaporous silicon tetrachloride 208 with surface hydroxyl groups 204 (and with whatever ambient moisture is present in the reaction environment, not shown), a layer of silicon oxide 210 is formed on the substrate surface 203. Depending on the amount of residual moisture (not shown) present in the processing chamber relative to the amount of silicon tetrachloride, not all of the Si—Cl groups 208 may be converted to an oxide. In the reacted structure 220B, there may be both unreacted —OH groups 204 or unreacted Si—Cl groups 216 depending on the ratio of silicon tetrachloride to water vapor. There may be some newly formed —OH moieties 214 (in the case of excess of water) present along with chlorine 216 (in the case of excess SiCl₄) within the generally silicon oxide structure 210 of reacted structure 220B.

FIG. 2B shows a reaction schematic where the processed substrate 2A-2 (220B) having residual —OH groups 204 or newly formed —OH groups 214 (or processed substrate 2A-1, not shown) is reacted with vaporous silicon tetrachloride 208 in the absence of moisture, to convert all OH groups to silicon oxide 210 and to create a chlorinated structure 232 on the top surface.

FIG. 2C is a reaction schematic where the starting substrate is substrate 230, with reactive chlorinated sites 216, which are exposed to a vapor of an organic molecule 242 which contains nucleophilic functional groups such as (—OH) functional groups 246 which react with the halogen moieties, chlorinated sites 216, to chemically bond the organic molecule 242 to the substrate 202, while producing HCl 212 as a reaction byproduct. Other organic molecules which make hydrogen available to react with the chlorine (or other halogen) can be used, as previously mentioned.

### DETAILED DESCRIPTION OF EXEMPLARY EMBODIMENTS

As a preface to the detailed description, it should be noted that, as used in this specification and the appended claims, the singular forms “a”, “an”, and “the” include plural referents, unless the context clearly dictates otherwise.

As a basis for understanding the invention, it is necessary to discuss the processing apparatus which permits precise control over the addition of coating precursors and other vaporous components present within the reaction/processing chamber in which the coating is applied. The apparatus described below is not the only apparatus in which the present invention may be practiced, it is merely an example of one apparatus which may be used. One skilled in the art will recognize equivalent elements in other forms which may be substituted and still provide an acceptable processing system.

I. An Apparatus for Vapor Deposition of Thin Coatings

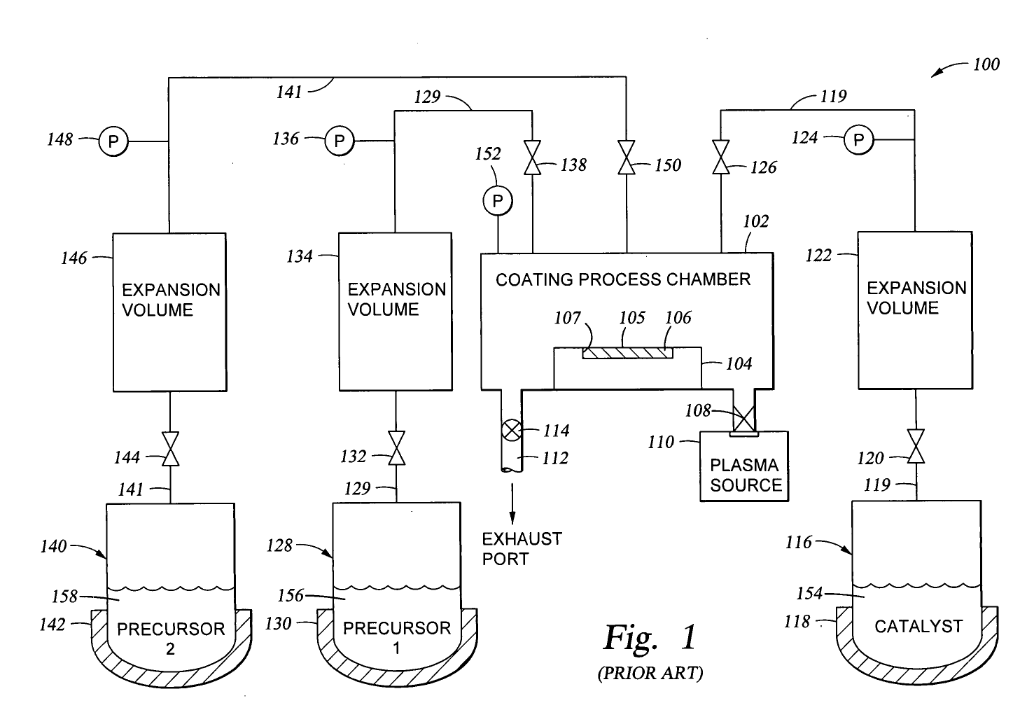

FIG. 1 shows a cross-sectional schematic of an apparatus 100 for vapor deposition of thin coatings. The apparatus 100 includes a process chamber 102 in which thin (typically 0.5 nm to 50 nm thick) coatings are vapor deposited. A substrate 106 to be coated rests upon a temperature controlled substrate holder 104, typically within a recess 107 in the substrate holder 104.

Depending on the chamber design, the substrate 106 may rest on the chamber bottom (not shown in this position in FIG. 1). Attached to process chamber 102 is a remote plasma source 110, connected via a valve 108. Remote plasma source 110 may be used to provide a plasma which is used to clean and/or convert a substrate surface to a particular chemical state prior to application of a coating (which enables reaction of coating species and/or catalyst with the surface, thus improving adhesion and/or formation of the coating); or may be used to provide species helpful during formation of the coating (not shown) or modifications of the coating after deposition. The plasma may be generated using a microwave, DC, or inductive RF power source, or combinations thereof. The process chamber 102 makes use of an exhaust port 112 for the removal of reaction byproducts and is opened for pumping/purging the chamber 102. A shut-off valve or a control valve 114 is used to isolate the chamber or to control the amount of vacuum applied to the exhaust port. The vacuum source is not shown in FIG. 1.

The apparatus 100 shown in FIG. 1 is illustrative of a vapor deposited coating which employs two precursor materials and a catalyst. One skilled in the art will understand that one or more precursors and from zero to multiple catalysts may be used during vapor deposition of a coating. A catalyst storage container 116 contains catalyst 154, which may be heated using heater 118 to provide a vapor, as necessary. It is understood that precursor and catalyst storage container walls, and transfer lines into process chamber 102 will be heated as necessary to maintain a precursor or catalyst in a vaporous state, minimizing or avoiding condensation. The same is true with respect to heating of the interior surfaces of process chamber 102 and the surface of substrate 106 to which the coating (not shown) is applied. A control valve 120 is present on transfer line 119 between catalyst storage container 116 and catalyst vapor reservoir 122, where the catalyst vapor is permitted to accumulate until a nominal, specified pressure is measured at pressure indicator 124. Control valve 120 is in a normally-closed position and returns to that position once the specified pressure is reached in catalyst vapor reservoir 122. At the time the catalyst vapor in vapor reservoir 122 is to be released, valve 126 on transfer line 119 is opened to permit entrance of the catalyst present in vapor reservoir 122 into process chamber 102 which is at a lower pressure. Control valves 120 and 126 are controlled by a programmable process control system of the kind known in the art (which is not shown in FIG. 1).

A Precursor 1 storage container 128 contains coating reactant Precursor 1, which may be heated using heater 130 to provide a vapor, as necessary. As previously mentioned, Precursor 1 transfer line 129 and vapor reservoir 134 internal surfaces are heated as necessary to maintain a Precursor 1 in a vaporous state, minimizing and preferably avoiding condensation. A control valve 132 is present on transfer line 129 between Precursor 1 storage container 128 and Precursor 1 vapor reservoir 134, where the Precursor 1 vapor is permitted to accumulate until a nominal, specified pressure is measured at pressure indicator 136. Control valve 132 is in a normally-closed position and returns to that position once the specified pressure is reached in Precursor 1 vapor reservoir 134. At the time the Precursor 1 vapor in vapor reservoir 134 is to be released, valve 138 on transfer line 129 is opened to permit entrance of the Precursor 1 vapor present in vapor reservoir 134 into process chamber 102, which is at a lower pressure. Control valves 132 and 138 are controlled by a programmable process control system of the kind known in the art (which is not shown in FIG. 1).

A Precursor 2 storage container 140 contains coating reactant Precursor 2, which may be heated using heater 142 to provide a vapor, as necessary. As previously mentioned, Precursor 2 transfer line 141 and vapor reservoir 146 internal surfaces are heated as necessary to maintain Precursor 2 in a vaporous state, minimizing, and preferably avoiding condensation. A control valve 144 is present on transfer line 141 between Precursor 2 storage container 146 and Precursor 2 vapor reservoir 146, where the Precursor 2 vapor is permitted to accumulate until a nominal, specified pressure is measured at pressure indicator 148. Control valve 141 is in a normally-closed position and returns to that position once the specified pressure is reached in Precursor 2 vapor reservoir 146. At the time the Precursor 2 vapor in vapor reservoir 146 is to be released, valve 150 on transfer line 141 is opened to permit entrance of the Precursor 2 vapor present in vapor reservoir 146 into process chamber 102, which is at a lower pressure. Control valves 144 and 150 are controlled by a programmable process control system of the kind known in the art (which is not shown in FIG. 1).

During formation of a coating (not shown) on a surface 105 of substrate 106, at least one incremental addition of vapor equal to the vapor reservoir 122 of the catalyst 154, and the vapor reservoir 134 of the Precursor 1, or the vapor reservoir 146 of Precursor 2 may be added to process chamber 102. The total amount of vapor added is controlled by both the adjustable volume size of each of the expansion chambers (typically 50 cc up to 1,000 cc) and the number of vapor injections (doses) into the reaction chamber. Further, the set pressure 124 for catalyst vapor reservoir 122, or the set pressure 136 for Precursor 1 vapor reservoir 134, or the set pressure 148 for Precursor 2 vapor reservoir 146, may be adjusted to control the amount (partial vapor pressure) of the catalyst or reactant added to any particular step during the coating formation process. This ability to control precise amounts of catalyst and vaporous precursors to be dosed (charged) to the process chamber 102 at a specified time provides not only accurate dosing of reactants and catalysts, but repeatability in the vapor charging sequence.

This apparatus provides a relatively inexpensive, yet accurate method of adding vapor phase precursor reactants and catalyst to the coating formation process, despite the fact that many of the precursors and catalysts are typically relatively non-volatile materials. In the past, flow controllers were used to control the addition of various reactants; however, these flow controllers may not be able to handle some of the precursors used for vapor deposition of coatings, due to the low vapor pressure and chemical nature of the precursor materials. The rate at which vapor is generated from some of the precursors is generally too slow to function with a flow controller in a manner which provides availability of material in a timely manner for the vapor deposition process.

The apparatus discussed above allows for accumulation of the specific quantity of vapor in the vapor reservoir which can be charged (dosed) to the reaction chamber. In the event it is desired to make several doses during the coating process, the apparatus can be programmed to do so, as described above. Additionally, adding of the reactant vapors into the reaction chamber in controlled aliquots (as opposed to continuous flow) greatly reduces the amount of the reactants used and the cost of the coating. In some cases precursor vapor can be collected directly in the reaction chamber by by-passing the vapor reservoir.

One skilled in the art of chemical processing of a number of substrates simultaneously will recognize that a processing system which permits heat and mass transfer uniformly over a number of substrate surfaces simultaneously may be used to carry out the present invention.

II. Exemplary Embodiments of the Method of the Invention:

A method of the invention provides for vapor-phase deposition of coatings, where a processing chamber of the kind, or similar to the processing chamber described above is employed. Each coating precursor is transferred in vaporous form to a precursor vapor reservoir in which the precursor vapor accumulates. A nominal amount of the precursor vapor, which is the amount required for a coating layer deposition is accumulated in the precursor vapor reservoir. The at least one coating precursor is charged from the precursor vapor reservoir into the processing chamber in which a substrate to be coated resides. In some instances at least one catalyst vapor is added to the process chamber in addition to the at least one precursor vapor, where the relative quantities of catalyst and precursor vapors are based on the physical characteristics to be exhibited by the coating. In some instances a diluent gas is added to the process chamber in addition to the at least one precursor vapor (and optional catalyst vapor). The diluent gas is chemically inert and is used to increase a total desired processing pressure, while the partial pressure amounts of coating precursors and optionally catalyst components are varied.

The example embodiments described below are with reference to the bonding of an organic molecule containing a nucleophilic functional group with a substrate surface presenting reactive halogen sites. The reactive halogen sites are created by a specialized treatment which is dependent on the substrate composition. The density of the reactive halogen sites on the substrate is controlled as a method of controlling the density of the organic molecule attachment on the substrate surface.

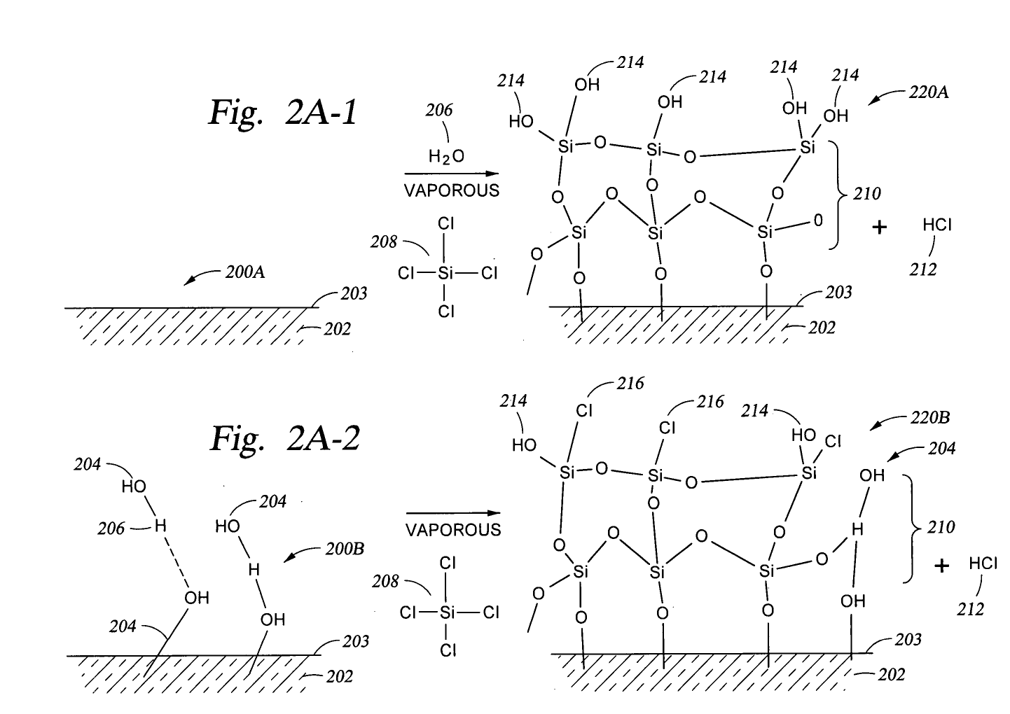

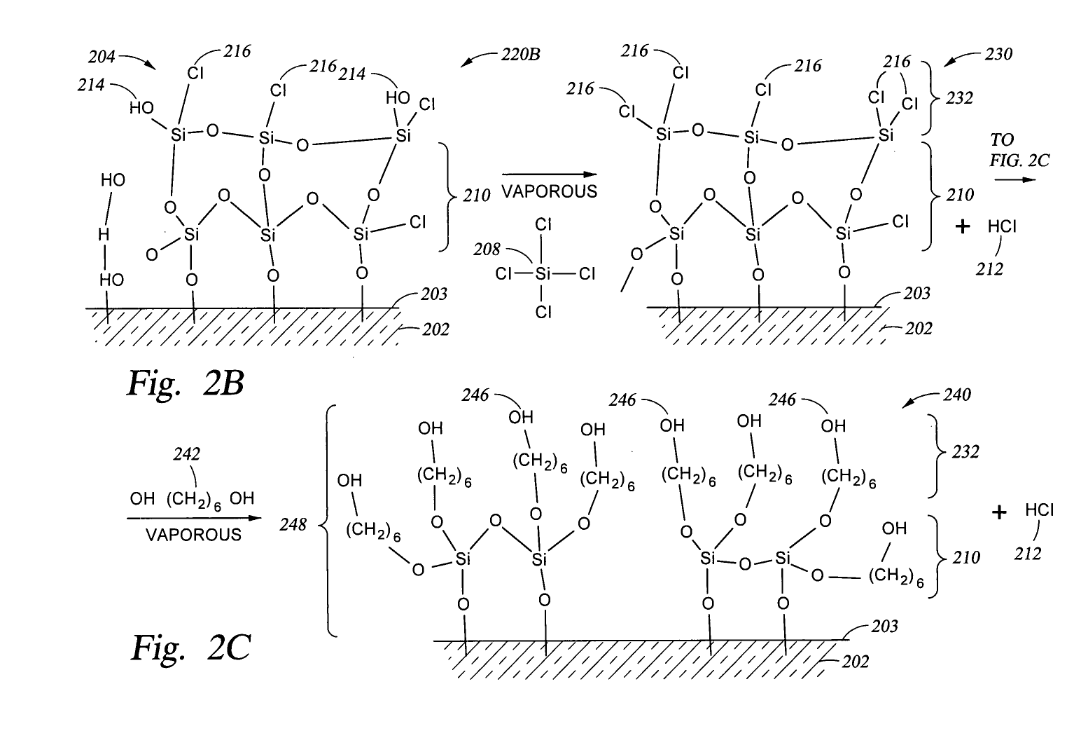

When the substrate surface is one which does not provide hydroxyl groups, as shown in FIG. 2A-1 (structure 200A), it is necessary to create an adhesion promoting layer 220A. This is typically done by first cleaning (not shown) substrate 202, commonly using an oxygen-containing plasma. The clean surface is then contacted with a combination of vaporous H₂O and a vaporous halogen-containing precursor, such as the silicon tetrachloride 208 shown in FIG. 2A-1. Depending on the relative amounts of the vaporous H₂O and SiCl₄, there are typically —OH moieties 214 present within the adhesion promoting layer 220A. A large portion of the adhesion promoting layer 220A is the silicon oxide structure 210. When there is excess SiCl₄ present, the water is consumed in the formation of silicon oxide on the substrate surface and some chlorine 216 may be present. This is independent of the substrate surface material composition. Typically the silicon oxide layer formed on the substrate surface is in the range of about 10 Å to about 200 Å in thickness. However, if it is desired to have a thicker layer of silicon oxide underlying the organic molecule to provide a particular mechanical behavior of the coated substrate, additional water and SiCl₄ can be added to the process chamber to form a thicker adhesion promoting layer. When the water is consumed, the oxide layer growth ceases.

When the substrate surface is one which does provide active hydroxyl groups 204 initially, as shown in FIG. 2A-2 (structure 200B) this substrate may be cleaned as described above if necessary. The active hydroxyl groups are then contacted with a vaporous halogen-containing reactant compound, such as the silicon tetrachloride 208 shown in FIG. 2A-2. The halogen-containing reactant compound is applied without adding water. There is typically some residual water vapor present in the processing chamber, and depending on the amount of water present (not shown) and the amount of SiCl₄ dosed, not all of the hydroxyl groups 204 may be converted to an oxide. In the reacted structure 220B, there may still be unreacted —OH groups 204. In addition, there may be some newly formed —OH moieties 214 present within the generally silicon oxide structure 210 of reacted structure 220B, until the water vapor is completely scavenged.

The generally silicon oxide structure 220A or 220B, is subsequently reacted with additional vaporous halogen-containing compound, illustrated as silicon tetrachloride 208 in FIG. 2B. This reaction with additional vaporous halogen-containing compound is carried out without removing the substrate from the processing chamber, so that all of the water vapor which might have initially been present in the process chamber has been scavenged. As a result, as shown in FIG. 2B, the reacted structure 230 obtained no longer has residual —OH moieties 204 or 214 present, and there is a surface of halogen moieties 216 available across the entire surface 203 of substrate 202.

In general, it is helpful to reduce the amount of water vapor which is initially present in the processing chamber environment, so that it is not necessary to consume as much halogen-containing compound during the organic coating formation process (and so that fewer water vapor scavenging cycles are required). The amount of water vapor initially present in the processing chamber environment is reduced by pumping down the process chamber to a pressure ranging between about 10 mTorr and about 1 Torr, with a lower pressure in the range of about 10 mTorr being preferred for maximum removal of water vapor. Pressures lower than 10 mTorr may be used, but this is more expensive, since the vacuum pump required is considerably more expensive. The process temperature at which the residual water vapor is scavenged by reaction with halogen-containing compound typically ranges from about 25° C. to about 100° C.

A chlorine-containing compound is often the more advantageous halogen-containing compound, because the HCl formed upon reaction with the —OH groups is easily removed from a process chamber at the pressures recited above. The chlorine-containing compound can be organic or inorganic, as long as the reaction with —OH groups is easily carried out and all reaction byproducts are volatile and easily removed from the processing chamber. Inorganic halogen-containing compounds have been demonstrated to work well. Chlorine-containing inorganic compounds such as SiCl₄, Si₂OCl₆, SnCl₂, PCl₅, and SOCl₂, by way of example, are sufficiently volatile to be used as vaporous reagents in the method of the invention.

Once the substrate surface is halogenated, any organic molecule containing a nucleophilic functional group which is not stearically hindered can be-attached to the halogenated surface. Examples of such nucleophilic functional groups include organic compounds such as RNH₂ and ROH, and organic compounds including ═NH, —SH, —SeH, —TeH and —PH₂ functional groups. Additional organic compounds which may be used include alkyl-lithium compounds (RLi: where R=C₄H₉, C₆H₁₃, and C₁₈H₃₇, by way of example). Alkyl-Grignard reagents may also be used (RMgX: where R=CH₃, C₂H₅, C₄H₉, C₅H_{11,C}6_{H}13, C₁₀H_{21,C}12_{H}25, and C₁₈H₃₇, and where X=Cl or Br). Gilman reagents are also useful as a source organic molecule containing functional groups. A Gilman reagent is a lithium and copper (diorganocopper) reagent compound, R_{—}{2}CuLi, where R is an organic radical. These reagents react with chlorides, bromides, and iodides to replace the halide group with an R group. The Gilman reagents can be used to create larger molecules from smaller ones.

As previously discussed, when the substrate surface to which the functional-group-containing organic molecule is to be attached does not present —OH sites, these sites must be created. Typically this is accomplished by creating an oxide layer on the substrate surface and then applying moisture to the oxide layer surface. Often it is advantageous to clean the substrate surface prior to creating the oxide layer. This may be done using a plasma or ozone treatment. A remotely generated plasma, generated from oxygen or an oxygen-containing compound can be fed into the process chamber to treat the substrate surface. This process removes any organic contamination from the substrate surface and activates it for reaction. An adhesion promoting oxide layer is then created on the substrate surface by treating the substrate surface with a combination of a gaseous halogen-containing compound (which useful in generating an oxide) and water vapor. The oxide provides a dense OH-terminated surface. This OH-terminated surface is then converted to a halogen-containing surface which can be reacted with an organic molecule containing a nucleophilic functional group in the manner described above.

### EXAMPLE ONE

### Controlling the Relative Quantities of Hydroxyl and Halogen Reactive Sites on a Substrate Surface

A technique for adjusting the number of OH reactive sites available on the surface of the substrate is to apply an oxide coating over the substrate surface while providing the desired concentration of OH reactive sites available on the oxide surface. In particular, in FIG. 2A-1 structure 200A which has no —OH groups 204 present on the substrate surface 203. A chlorine-containing compound, such as the silicon tetrachloride 208 shown, and water 206 are reacted with the surface 203, either in sequence (typically with the chlorine-containing compound charged to the reactor first) or simultaneously to produce the oxide layer 210 shown on surface 203 of substrate 202 and byproduct HCl 212. When the quantity of water vapor 206 (the water vapor partial pressure in the process chamber) present relative to the amount of silicon tetrachloride gas 208 (the silicon tetrachloride vapor partial pressure) is in the range of about 4:1 to about 10:1, the chlorine atoms 216 shown at the top of the oxide layer 210 will be reacted to form additional —OH groups (not shown). When the quantity of water vapor 206 present relative to the amount of silicon tetrachloride gas 208 is in the range of less than 0.2:1, the chlorine atoms 216 will be present on the upper surface of the deposited layer 210 as shown in FIG. 2B structure 230, to provide a halogenated substrate surface. Various degrees of halogenation of the substrate surface can be obtained by controlling the relative vapor pressures of water and halogen-containing compound during the reaction process, and by scavenging away all of the water vapor using the halogenated-compound, as previously described. The degree of halogenation with all other variables held constant is also affected by the temperature of the substrate and the processing chamber surfaces.

A halogenated substrate surface can subsequently be reacted with an organic molecule containing a nucleophilic functional group to provide an organic coating which may exhibit residual functional groups upon which further reactive processes may be carried out. For example, subsequent to the reaction shown in FIG. 2B, the halogenated surface 216 of the oxide layer 210 can be further reacted as shown in FIG. 2C to provide the organic coating described above.

### EXAMPLE TWO

### Demonstration of Control of Concentration of Halogen Reactive Sites on a Substrate Surface

In the exemplary embodiments discussed below, a silicon oxide coating was applied over a substrate. The substrate was a silicon substrate, which was first treated with an oxygen plasma in the presence of residual moisture which was present in the process chamber (after pump down of the chamber to about 20 mTorr) to provide a clean surface (free from organic contaminants). Because the substrate was silicon, this treatment also provides —OH groups on the silicon surface. A typical plasma treatment process is one carried out in the processing chamber apparatus described herein using a remotely generated plasma. The remotely generated plasma is generated from a plasma source gas containing oxygen at a volumetric percentage ranging from about 50% oxygen up to about 100% oxygen. An RF power is applied to the plasma source gas using techniques known in the art to generate a plasma. In the present instance, for a plasma source gas of about 99.9% oxygen, flowing at a rate of about 20-100 sccm, 200 W of RF power at 13.56 MHz was applied to generate the plasma in a chamber which was at a temperature ranging from about 25° C. to about 60° C. The plasma was fed through a tube into the substrate processing chamber, and the substrate was contacted with the plasma for a period of about 1 minutes to about 5 minutes. The pressure in the processing chamber during the plasma treatment was typically in the range of about 0.1 Torr to about 0.5 Torr.

Table I, below indicated different process conditions which were used for the subsequent reaction of the OH groups on the silicon surface. The process chamber was first pumped down to 15 mTorr at 60° C., to remove as much of the residual moisture in the process chamber as possible. In the first experimental run, after pump down of the chamber, the substrate surface was treated with vaporous tetrachlorosilane only. In the second experimental run, after pump down of the chamber, the substrate surface was treated with a combination of vaporous tetrachlorosilane and water vapor. In each case, following the creation of chlorine sites on the surface of the substrate, the substrate surface was contacted with hexane diol to form an organic coating with —OH functional groups on the surface of the substrate. The water-based contact angle was then measured for each of the coated substrates, to demonstrate the difference in the amount of chlorine sites which were present to react with the hexanediol. The larger the number of reactive chlorine sites, the higher the density of organic molecules on the substrate surface, and the higher the contact angle with the water droplet.

In both experimental runs, the treatment with the SiCl₄ or SiCl₄ and H₂O reactants was carried out three times. There were three reaction cycles where the SiCl₄ or SiCl₄ and H₂O reactants were recharged to the process chamber and reacted, followed by pump down of the process chamber to 15 mTorr at the end of each reaction cycle. The temperature in the process chamber for halogenation of the substrate surface may range from about 25° C. to about 100° C.; the temperature for these experimental runs was 60° C. The reaction time period for the halogenation of the substrate may range from about 3 minutes to about 30 minutes per cycle; the reaction time period for each cycle during these experimental runs was 3 minutes. The use of three reaction cycles was done to make certain that residual moisture in the process chamber was fully scavenged and that the surface created was that which would be created by the partial pressure(s) of the reactive compounds shown in the table above.

In both experimental runs, after completion of the halogenation of the substrate surface, the substrate surface was reacted with hexanediol. The vapor pressure of the hexanediol 242 in the process chamber may be in the range from about 0.1 Torr to about 0.3 Torr; for these experimental runs, the hexanediol vapor pressure was 0.3 Torr. The temperature in the process chamber may be in the range of about 25° C. to about 100° C.; for these experimental runs, the temperature was 60° C. The reaction time period for the hexanediol may range from about 15 minutes to about 30 minutes; for these experimental runs, the time of reaction was 30 minutes. After completion of the reaction, excess hexanediol was pumped out of the process chamber, using a vacuum pump, down to about 15 mTorr. The contact angle was measured using a Rame-Hart Goniometer, Model 100 apparatus available from Rame-Hart, following the drop shape analysis test method. In the present instance only one reaction cycle with hexanediol was used. In other instances, it may be advantageous to use more than one hexanediol reaction cycle, with a pump down of process chamber volume prior to the charging of hexane diol for each new reaction cycle.

TABLE I
Concentration of Halogen Reactive Sites
As Indicated By Contact Angle

| | | | Water Droplet |
|---|---|---|---|
| | SiCl₄ Vapor | H₂O Vapor | Contact |
| Run | Partial Pressure | Partial Pressure | Angle* |
| No. | (Torr) | (Torr) | (°) |
| 1 | 4.0 | 0.0 | 55 |
| 2 | 4.0 | 1.0 | 31 |

*Contact angle measured after treatment of the substrate surface to attach halogen reactive sites, followed by reaction of the substrate surface with hexanediol.
The theoretical contact angle for hexane diol ranges from about 45° to about 55°. Thus, the 55° contact angle measured indicates complete surface coverage of the substrate with hexane diol.
The 31° contact angle measured when water was added to the process chamber at a ratio of 1:4 with respect to SiCl₄ indicates that there was a lesser degree of surface coverage by hexane diol. This is expected if only a portion of the —OH groups present on the substrate are converted to chlorine sites.

The data presented above shows that to obtain a complete chlorination of the substrate surface, the ratio of H₂O to SiCl₄ should be less than 1:4, typically less than 1:5, as a safety factor.

Functional properties designed to meet the end use application of the finalized product can be tailored by application of a particular organic molecule to the halogenated substrate surface of the kind shown in the schematic FIG. 2B, structure 230. FIG. 2C illustrates the application of vaporous hexanediol 242 to the halogenated substrate surface shown in FIG. 2B structure 230. The vaporous hexanediol 242 was added to the process chamber in which the halogenation (chlorination) of the substrate surface 203 was previously carried out, without the introduction of any moisture to the chamber between halogenation and reaction with hexanediol, to avoid the conversion of the chlorine sites 216 to hydroxyl groups (which would occur if the silicon-chlorine bonds were exposed to a moisture-containing ambient atmosphere). As an alternative to carrying out the reaction with the organic molecule in the chamber in which the halogen is attached to the substrate, it is possible to transfer the substrate to another chamber prior to reaction with the organic molecule, so long as the transfer is carried out under conditions which maintain isolation from moisture and other contaminants which affect the surface reaction product.

The above described exemplary embodiments are not intended to limit the scope of the present invention, as one skilled in the art can, in view of the present disclosure expand such embodiments to correspond with the subject matter of the invention claimed below.

We claim:

1. A method of depositing an organic coating on a substrate from a vapor phase organic-comprising precursor, wherein said substrate surface upon which said organic coating is applied is a halogenated surface which was produced by treatment of said substrate with a vaporous, halogen-containing compound in a process chamber under vacuum conditions, and wherein said organic-comprising precursor contains at least one nucleophilic functional group which reacts with said halogenated surface to attach an organic coating to said surface.

2. A method in accordance with claim 1, wherein the density of reactive halogen sites on said halogenated surface is controlled by controlling the amount of a vaporous halogen-containing compound which is contacted with said substrate surface in a process chamber under vacuum conditions.

3. A method in accordance with claim 1 or claim 2, wherein said vacuum conditions refer to a process chamber pressure ranging from about 1 mTorr to about 10 Torr.

4. A method in accordance with claim 3, wherein process chamber pressure ranges from about 10 mTorr to about 1 Torr.

5. A method in accordance with claim 1 or claim 2, wherein said vaporous halogen-containing compound contains chlorine.

6. A method in accordance with claim 1 or claim 2, wherein said vaporous halogen-containing compound is selected from the group consisting of chlorosilanes, chlorosiloxanes, fluorosilanes, fluorosiloxanes and combinations thereof.

7. A method in accordance with claim 6, wherein said halogen-containing compound is a chlorine-containing compound.

8. A method in accordance with claim 1 or claim 2, wherein water is added to said processing chamber for use in combination with said halogen-containing compound, to provide said halogenated surface.

9. A method in accordance with claim 8, wherein an amount of water added to said processing chamber is used to control the density of said the relative amount of reactive halogen-containing sites on said halogenated surface.

10. A method in accordance with claim 1, wherein said treatment of said surface with said halogen-containing compound is carried out using a plurality of treatment cycles, and wherein each cycle includes charging of a nominal amount of said halogen-containing compound, and reaction of said halogen containing compound with said substrate, followed by a pump down of said process chamber to remove halogenation process byproducts, halogen-containing compound residue, or combinations thereof.

11. A method in accordance with claim 8, wherein said treatment of said surface with said halogen-containing compound and water is carried out using a plurality of treatment cycles, and wherein each cycle includes charging of a nominal amount of said halogen-containing compound and a nominal amount of said water, and reaction of said halogen containing compound and water with said substrate, followed by a pump down of said process chamber to remove halogenation process byproducts, halogen-containing compound residue, or combinations thereof.

12. A method in accordance with claim 8, wherein said halogen-containing compound is SiCl₄, and wherein the ratio of water vapor partial pressure to SiCl₄ vapor pressure in a process chamber in which the substrate surface is treated is less than 1:4.

13. A method in accordance with claim 3, wherein a total pressure in said process chamber in which said vaporous halogen-containing compound treatment is carried out is in the range of about 1 Torr to about 3 Torr.

14. A method in accordance with claim 3, wherein a temperature in said process chamber during said treatment ranges from about 25° C. to about 100° C.

15. A method in accordance with claim 14, wherein said temperature ranges from about 25° C. to about 60° C.

16. A method in accordance with claim 1 or claim 2, wherein said organic-comprising precursor is selected from the group consisting of organic compounds having the formula RNH₂ or ROH; organic compounds including ═NH, —SH, —SeH, —TeH and —PH₂ functional groups; alkyl-lithium compounds, RLi; Alkyl-Grignard reagents, RMgX; and Gilman reagents, R_{—}{2}CuLi; wherein R is an organic radical.

17. A method in accordance with claim 1 or claim 2, wherein subsequent to halogenation of said substrate surface and prior to reaction of said halogenated substrate surface with said organic-comprising compound, said halogenated substrate surface is isolated from contact with moisture and other contaminants which affect the reaction product of said halogenated substrate surface with said organic-comprising compound.

18. A method in accordance with claim 17, wherein said isolation is achieved by carrying out said halogenation of said substrate surface and said subsequent reaction of said halogenated surface with said organic-comprising compound in the same process chamber without removing said substrate from said process chamber.

19. A method of attaching an organic coating to a surface of a substrate at a controlled density upon said substrate, wherein said organic coating is formed by reacting a vapor phase organic-comprising precursor containing at least one nucleophilic functional group with a halogen species attached to said substrate surface, and wherein said halogen species are attached to said substrate by treatment of said substrate with a vaporous, halogen-containing compound.

20. A method in accordance with claim 19, wherein said attachment is by covalent bonding.

21. A method in accordance with claim 19, wherein said density of attachment of said organic coating is controlled by a density of said halogen species attached to said substrate surface, and wherein the density of attachment of said halogen species is controlled by the amount of a vaporous halogen-containing compound which is contacted with said substrate surface in a process chamber under vacuum conditions.

22. A method in accordance with claim 19, wherein the density of attachment of said halogen species is controlled by an amount of water added either prior to or during the attachment of said halogen species.

23. A method in accordance with claim 21, wherein said treatment of said surface with said halogen-containing compound is carried out using a plurality of treatment cycles, and wherein each cycle includes charging of a nominal amount of said halogen-containing compound, and reaction of said halogen containing compound with said substrate, followed by a pump down of said process chamber to remove halogenation process byproducts, halogen-containing compound residue, or combinations thereof.

24. A method in accordance with claim 22 wherein said treatment of said surface with said halogen-containing compound and water is carried out using a plurality of treatment cycles, and wherein each cycle includes charging of a nominal amount of said halogen-containing compound and a nominal amount of said water, and reaction of said halogen containing compound and water with said substrate, followed by a pump down of said process chamber to remove halogenation process byproducts, halogen-containing compound residue, or combinations thereof.

25. A method in accordance with claim 24, wherein said halogen-containing compound is SiCl₄, and wherein the ratio of water vapor partial pressure to SiCl₄ vapor pressure in a process chamber in which the substrate surface is treated is less than 1:4.
